(19) United States
(12) Patent Application Publication
(10) Pub. No.: US 2019/0386604 A1
(43) Pub. Date: Dec. 19, 2019

(54) CASCADED SOLAR CELL STRING USING ADHESIVE CONDUCTIVE FILM

(71) Applicant: TESLA, INC., Palo Alto, CA (US)

(72) Inventor: Bhavananda R. Nadimpally, San Jose, CA (US)

(73) Assignee: TESLA, INC., Palo Alto, CA (US)

(21) Appl. No.: 16/007,599

(22) Filed: Jun. 13, 2018

(51) Int. Cl. H02S 20/25; H02S 40/36; H01L 31/048; H01L 31/18

(52) U.S. Cl. CPC H02S 20/25; H01L 31/1876; H01L 31/0488; H02S 40/36

(57) ABSTRACT

One embodiment can provide a photovoltaic roof tile. The photovoltaic roof tile can include a front cover, a back cover, and a plurality of photovoltaic structures positioned between the front and back covers. A respective photovoltaic structure can include a first edge busbar positioned near an edge of a first surface and a second edge busbar positioned near an opposite edge of a second surface. The plurality of photovoltaic structures can be arranged in such a way that the first edge busbar of a first photovoltaic structure overlaps the second edge busbar of an adjacent photovoltaic structure with a layer of adhesive conductive film sandwiched between the first and second edge busbars, thereby resulting in the plurality of photovoltaic structures forming a serially coupled string.

### BACKGROUND

### Field

This disclosure is generally related to photovoltaic (or “PV”) structures. More specifically, this disclosure is related to a system and method for fabricating cascaded photovoltaic strings.

### Related Art

Continued advances in photovoltaics are making it possible to generate ever-increasing amounts of energy using solar panels. These advances also help solar energy gain mass appeal from ordinary consumers who wish to reduce their carbon footprint and decrease their monthly energy expenses. However, complete solar panels are typically fabricated manually, which is a time-consuming and error-prone process that makes it costly to mass-produce solar panels in high volumes.

Typical solar panels can be manufactured by constructing continuous strings of complete solar cells, and combining these strings to form a solar panel. A string can include several complete solar cells that overlap one another in a cascading arrangement. Continuous strings of solar cells that form a solar panel exist, and are described in U.S. patent application Ser. No. 14/510,008, filed Oct. 8, 2014, and entitled “Module Fabrication of Solar Cells with Low Resistivity Electrodes.” Producing solar panels with a cascaded cell arrangement can reduce inter-connection resistance between two strips, and can increase the number of solar cells that can fit into a solar panel.

In addition to conventional rooftop panels, PV or solar roof tiles have recently been developed to enhance the aesthetics of PV modules. A PV roof tile can be shaped like a conventional roof tile and can include one or more solar cells encapsulated between a front cover and a back cover, but typically encloses fewer solar cells than a conventional solar panel. The front and back covers can be fortified glass or other material that can protect the PV cells from the weather elements. Similar to a PV panel, a PV roof tile can also include cascaded solar cells or strips. FIG. 1 shows an exemplary configuration of PV roof tiles on a house. PV roof tiles 100 can be installed on a house like conventional roof tiles or shingles. Particularly, a PV roof tile can be placed with other tiles in such a way as to prevent water from entering the building.

Manufacturing a cascaded panel or roof tile can involve connecting two photovoltaic structures by edge overlapping the structures so that the metal layers (e.g., busbars) on each side of the overlapped structures establish an electrical connection. This process can be repeated for a number of successive structures until one string of cascaded cells is created. To ensure mechanical and electrical contact between adjacent structures of a cascaded string, electrically conductive paste has been used to bond the overlapping metal layers. However, precise application of conductive paste can be difficult and overflowing paste can lead to solar cell failure. Moreover, using conductive paste to bond overlapping solar cells can also be costly.

### SUMMARY

One embodiment can provide a photovoltaic roof tile. The photovoltaic roof tile can include a front cover, a back cover, and a plurality of photovoltaic structures positioned between the front and back covers. A respective photovoltaic structure can include a first edge busbar positioned near an edge of a first surface and a second edge busbar positioned near an opposite edge of a second surface. The plurality of photovoltaic structures can be arranged in such a way that the first edge busbar of a first photovoltaic structure overlaps the second edge busbar of an adjacent photovoltaic structure with a layer of adhesive conductive film sandwiched between the first and second edge busbars, thereby resulting in the plurality of photovoltaic structures forming a serially coupled string.

In a variation on this embodiment, the front cover can include tempered glass.

In a variation on this embodiment, the back cover can include tempered glass, a photovoltaic backsheet, flexible glass, garolite, or glass-epoxy laminate.

In a variation on this embodiment, the adhesive conductive film layer can include an anisotropic conductive film (ACF) or a double-sided conductive tape.

In a variation on this embodiment, the adhesive conductive film can be deposited onto a surface of at least one of the first and second edge busbars.

In a further variation, the adhesive conductive film can be configured to completely cover the surface of the at least one of the first and second edge busbars.

In a further variation, the adhesive conductive film can be configured to partially cover the surface of the at least one of the first and second edge busbars.

In a variation on this embodiment, the photovoltaic roof tile can further include one or more external conductive connectors coupled to one or more exposed edge busbars of the serially coupled string.

In a further variation, the external conductive connectors can include a strain-relief connector, which can include an elongated connection member, a number of curved metal wires, laterally extended from one side of the elongated connection member, and a number of connection pads.

In a variation on this embodiment, the first and second edge busbars can include a Cu layer and a corrosion-protective layer. The corrosion-protective layer can include a corrosion-resistant metal layer or an organic solderability preservative (OSP) coating.

One embodiment can provide a method for fabricating a photovoltaic roof tile. The fabrication method can include obtaining a number of photovoltaic structures. A respective photovoltaic structure comprises a first edge busbar positioned near an edge of a first surface and a second edge busbar positioned near an opposite edge of a second surface. The fabrication method can further include applying an adhesive conductive film layer on at least one of the first and second edge busbars, forming a cascaded string of photovoltaic structures by arranging the photovoltaic structures in such a way that the first edge busbar of a first photovoltaic structure overlaps the second edge busbar of an adjacent photovoltaic structure with the adhesive conductive film layer sandwiched between the first and second edge busbars, and laminating the cascaded string of photovoltaic structures between a front cover and a back cover.

A “solar cell” or “cell” is a photovoltaic structure capable of converting light into electricity. A cell may have any size and any shape, and may be created from a variety of materials. For example, a solar cell may be a photovoltaic structure fabricated on a silicon wafer or one or more thin films on a substrate material (e.g., glass, plastic, or any other material capable of supporting the photovoltaic structure), or a combination thereof.

A “solar cell strip,” “photovoltaic strip,” “smaller cell,” or “strip” is a portion or segment of a photovoltaic structure, such as a solar cell. A photovoltaic structure may be divided into a number of strips. A strip may have any shape and any size. The width and length of a strip may be the same or different from each other. Strips may be formed by further dividing a previously divided strip.

“Finger lines,” “finger electrodes,” and “fingers” refer to elongated, electrically conductive (e.g., metallic) electrodes of a photovoltaic structure for collecting carriers.

“Busbar,” “bus line,” or “bus electrode” refer to elongated, electrically conductive (e.g., metallic) electrodes of a photovoltaic structure for aggregating current collected by two or more finger lines. A busbar is usually wider than a finger line, and can be deposited or otherwise positioned anywhere on or within the photovoltaic structure. A single photovoltaic structure may have one or more busbars. It is also possible for a photovoltaic structure to have no busbar.

A “photovoltaic structure” can refer to a solar cell, a segment, or a solar cell strip. A photovoltaic structure is not limited to a device fabricated by a particular method. For example, a photovoltaic structure can be a crystalline silicon-based solar cell, a thin film solar cell, an amorphous silicon-based solar cell, a polycrystalline silicon-based solar cell, or a strip thereof.

### BRIEF DESCRIPTION OF THE FIGURES

FIG. 1 shows an exemplary configuration of PV roof tiles on a house.

FIG. 2A shows an exemplary grid pattern on the front surface of a photovoltaic structure, according to one embodiment of the present invention.

FIG. 2B shows an exemplary grid pattern on the back surface of a photovoltaic structure, according to one embodiment of the invention.

FIG. 3A shows a string of cascaded strips, according to an embodiment of the invention.

FIG. 3B shows a side view of the string of cascaded strips, according to one embodiment of the invention.

FIG. 4 shows a cross-section of an exemplary photovoltaic roof tile, according to an embodiment.

FIG. 5 illustrates a top view of an exemplary solar roof tile that encapsulates a cascaded string, according to one embodiment.

FIG. 6A shows the top view of an exemplary multi-tile module, according to one embodiment.

FIG. 6B shows a detailed view of an exemplary strain-relief connector, according to one embodiment.

FIG. 6C shows the top view of an exemplary multi-tile module, according to one embodiment.

FIG. 7 illustrates a photovoltaic structure with conductive paste applied onto its busbars (prior art).

FIG. 8A illustrates a surface of a photovoltaic structure with adhesive conductive films applied onto its busbars, according to one embodiment.

FIG. 8B illustrates a surface of a photovoltaic strip with an adhesive conductive film applied onto its edge busbar, according to one embodiment.

FIG. 8C illustrates a surface of a photovoltaic strip with an adhesive conductive layer applied onto its edge busbar, according to one embodiment.

FIG. 9A illustrates the cross-section of an exemplary photovoltaic roof tile, according to an embodiment.

FIG. 9B illustrates the cross-section of an exemplary photovoltaic roof tile, according to an embodiment.

FIG. 10 presents a flowchart illustrating an exemplary process for fabricating a photovoltaic module, according to an embodiment.

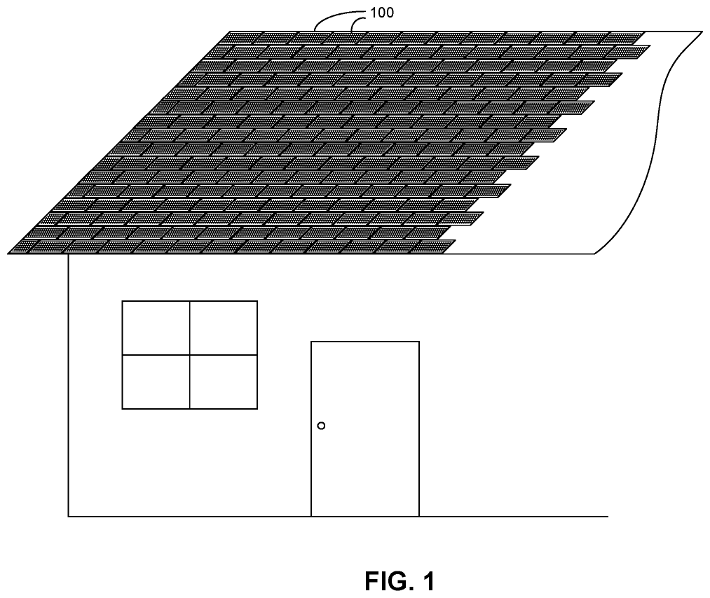

In the figures, like reference numerals refer to the same figure elements.

### DETAILED DESCRIPTION

The following description is presented to enable any person skilled in the art to make and use the embodiments, and is provided in the context of a particular application and its requirements. Various modifications to the disclosed embodiments will be readily apparent to those skilled in the art, and the general principles defined herein may be applied to other embodiments and applications without departing from the spirit and scope of the present disclosure. Thus, the disclosed system is not limited to the embodiments shown, but is to be accorded the widest scope consistent with the principles and features disclosed herein.

### Overview

Embodiments of the invention solve at least the technical problem of large-scale manufacturing of solar panels or roof tiles that include cascaded photovoltaic strings. More specifically, a layer of conductive film can be applied on the edge busbars of adjacent photovoltaic structures to enable reliable electrical and mechanical coupling between these adjacent photovoltaic structures within a cascaded string.

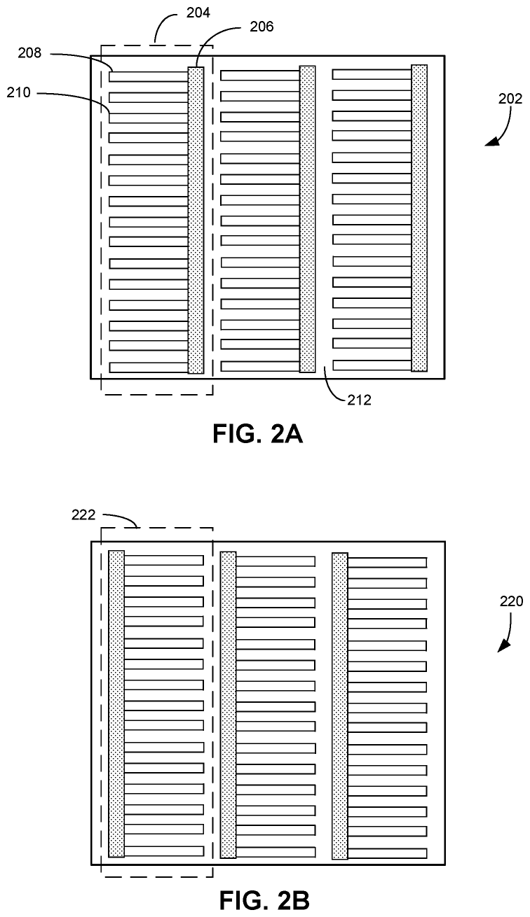

During fabrication, photovoltaic structures, which can include multi-layer semiconductor structures, may first be fabricated using crystalline silicon wafers. In some embodiments, the multi-layer semiconductor structure can include a double-sided tunneling heterojunction solar cell. The photovoltaic structures can be based on any size wafers (e.g., 5-inch or 6-inch wafers) and may have the shape of a square or pseudo-square with chamfered or rounded corners. Other shapes are possible as well. In some embodiments, the photovoltaic structures may be 6×6-inch square cells. Subsequently, front- and back-side conductive grids may be deposited on the front and back surfaces of the photovoltaic structures respectively to complete the bifacial photovoltaic structure fabrication (see FIGS. 2A and 2B).

In some embodiments, depositing the front- and back-side conductive grids may include depositing (e.g., electroplating) a Cu grid, which may be subsequently coated with Ag or Sn. In other embodiments, one or more seed metallic layers, such as a seed Cu or Ni layer, can be deposited onto the multi-layer structures using a physical vapor deposition (PVD) technique to improve adhesion and ohmic contact quality of the electroplated Cu layer. Instead of Ag- or Sn-based protective layer, in some embodiments, the Cu grid can also be coated with an organic layer to prevent corrosion and oxidation.

PV Tiles with Cascaded Solar Cell Strings

Some conventional solar panels include a single string of serially connected standard-size, undivided photovoltaic structures. As described in U.S. patent application Ser. No. 14/563,867, it can be desirable to have multiple (such as three) strings, each string including cascaded strips, and connect these strings in parallel. Such a multiple-parallel-string panel configuration provides the same output voltage with a reduced internal resistance. In general, a cell can be divided into n strips, and a panel can contain n strings, each string having the same number of strips as the number of regular photovoltaic structures in a conventional single-string panel. Such a configuration can ensure that each string outputs approximately the same voltage as a conventional panel. The n strings can then be connected in parallel to form a panel. As a result, the panel's voltage output can be the same as that of the conventional single-string panel, while the panel's total internal resistance can be 1/n of the resistance of a string. Therefore, in general, the greater n is, the lower the total internal resistance of the panel, and the more power one can extract from the panel. However, a tradeoff is that as n increases, the number of connections required to inter-connect the strings also increases, which increases the amount of contact resistance. Also, the greater n is, the more strips a single cell needs to be divided into, which increases the associated production cost and decreases overall reliability due to the larger number of strips used in a single panel.

Another consideration in determining n is the contact resistance between the electrode and the photovoltaic structure on which the electrode is formed. The greater this contact resistance, the greater n might need to be to reduce effectively the panel's overall internal resistance. Hence, for a particular type of electrode, different values of n might be needed to attain sufficient benefit in reduced total panel internal resistance to offset the increased production cost and reduced reliability. For example, conventional silver paste or aluminum-based electrode may require n to be greater than 4, because the process of screen printing and firing silver paste onto a cell does not produce ideal resistance between the electrode and underlying photovoltaic structure. In some embodiments of the present invention, the electrodes, including both the busbars and finger lines, can be fabricated using a combination of physical vapor deposition (PVD) and electroplating of copper as an electrode material. The resulting copper electrode can exhibit lower resistance than an aluminum or screen printed silver paste electrode. Consequently, a smaller n can be used to attain the benefit of reduced panel internal resistance. In some embodiments, n is selected to be three, which is less than the n value generally needed for cells with silver paste electrodes or other types of electrodes. Correspondingly, two grooves can be scribed on a single cell to allow the cell to be divided into three strips.

In addition to lower contact resistance, electro-plated copper electrodes can also offer better tolerance to micro cracks, which may occur during a cleaving process. Such microcracks might adversely affect silver paste electrode cells. Plated-copper electrode, on the other hand, can preserve the conductivity across the cell surface even if there are microcracks in the photovoltaic structure. The copper electrode's higher tolerance for microcracks allows one to use thinner silicon wafers to manufacture cells. As a result, the grooves to be scribed on a cell can be shallower than the grooves scribed on a thicker wafer, which in turn helps increase the throughput of the scribing process. More details on using copper plating to form low-resistance electrode on a photovoltaic structure are provided in U.S. patent application Ser. No. 13/220,532, entitled “SOLAR CELL WITH ELECTROPLATED GRID,” filed Aug. 29, 2011, the disclosure of which is incorporated herein by reference in its entirety.

FIG. 2A shows an exemplary grid pattern on the front surface of a photovoltaic structure, according to one embodiment of the present invention. In the example shown in FIG. 2A, grid 202 can include three sub-grids, such as sub-grid 204. This three sub-grid configuration allows the photovoltaic structure to be divided into three strips. To enable cascading, each sub-grid needs to have an edge busbar, which can be located either at or near the edge. In the example shown in FIG. 2A, each sub-grid includes an edge busbar (“edge” here refers to the edge of a respective strip) running along the longer edge of the corresponding strip and a plurality of parallel finger lines running in a direction parallel to the shorter edge of the strip. For example, sub-grid 204 can include edge busbar 206, and a plurality of finger lines, such as finger lines 208 and 210. Alternatively, a sub-grid can include an edge busbar running along the shorter edge of the strip and a plurality of parallel finger lines running in a direction parallel to the longer edge of the strip. To facilitate the subsequent laser-assisted scribe-and-cleave process, a predefined blank space (i.e., space not covered by electrodes) is inserted between the adjacent sub-grids. For example, blank space 212 separates two adjacent sub-grids. In some embodiments, the width of the blank space, such as blank space 212, can be between 0.1 mm and 5 mm, preferably between 0.5 mm and 2 mm. There is a tradeoff between a wider space that leads to more tolerant scribing operation and a narrower space that leads to more effective current collection. In a further embodiment, the width of such a blank space can be approximately 1 mm.

FIG. 2B shows an exemplary grid pattern on the back surface of a photovoltaic structure, according to one embodiment of the invention. In the example shown in FIG. 2B, back grid 220 includes three sub-grids, such as sub-grid 222. To enable cascaded and bifacial operation, the back sub-grid needs to correspond to the frontside sub-grid. More specifically, the back edge busbar needs to be located at the opposite edge of the frontside edge busbar. In the examples shown in FIGS. 2A and 2B, the front and back sub-grids have similar patterns except that the front and back edge busbars are located adjacent to opposite edges of the strip. In addition, locations of the blank spaces in back metal grid 220 correspond to locations of the blank spaces in front metal grid 202, such that the grid lines do not interfere with the subsequent scribe-and-cleave process. In practice, the finger line patterns on the front and back sides of the photovoltaic structure may be the same or different.

In the examples shown in FIGS. 2A and 2B, the finger line patterns can include continuous, non-broken loops. For example, as shown in FIG. 2A, finger lines 208 and 210 both include connected loops with rounded corners. This type of “looped” finger line pattern can reduce the likelihood of the finger lines peeling away from the photovoltaic structure after a long period of usage. Optionally, the sections where parallel lines are joined can be wider than the rest of the finger lines to provide more durability and prevent peeling. Patterns other than the one shown in FIGS. 2A and 2B, such as un-looped straight lines or loops with different shapes, are also possible.

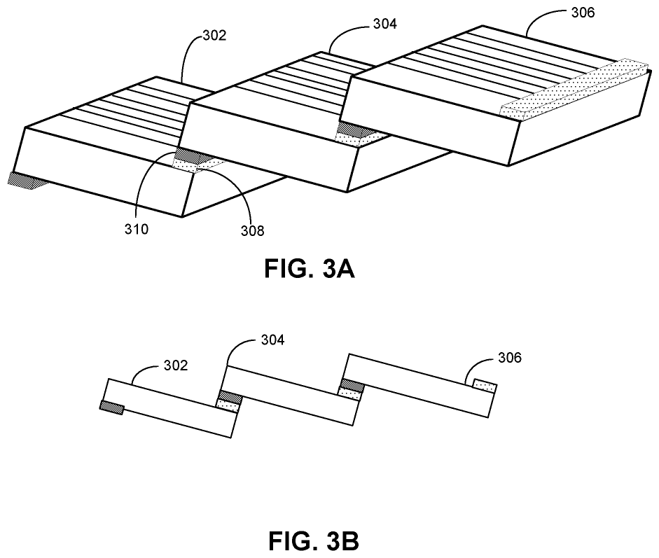

To form a cascaded string, strips (as a result of a scribing and cleaving process applied to a regular square cell) can be cascaded with their edges overlapped. FIG. 3A shows a string of cascaded strips, according to an embodiment of the invention. In FIG. 3A, strips 302, 304, and 306 are stacked in such a way that strip 306 partially overlaps adjacent strip 304, which also partially overlaps (on an opposite edge) strip 302. Such a string of strips forms a pattern that is similar to roof shingles. Each strip includes top and bottom edge busbars located at opposite edges of the top and bottom surfaces, respectively. Strips 302 and 304 are coupled to each other via an edge busbar 308 located at the top surface of strip 302 and an edge busbar 310 located at the bottom surface of strip 304. To establish electrical coupling, strips 302 and 304 are placed in such a way that bottom edge busbar 310 is placed on top of and in direct contact with top edge busbar 308.

FIG. 3B shows a side view of the string of cascaded strips, according to one embodiment of the invention. In the example shown in FIGS. 3A and 3B, the strips can be part of a 6-inch square photovoltaic structure, with each strip having a dimension of approximately 2 inches by 6 inches. To reduce shading, the overlapping between adjacent strips should be kept as small as possible. In some embodiments, the single busbars (both at the top and the bottom surfaces) are placed at the edge of the strip (as shown in FIGS. 3A and 3B) but could be placed anywhere that is convenient, such as near the edge. The same cascaded pattern can extend along an entire row of strips to form a serially connected string.

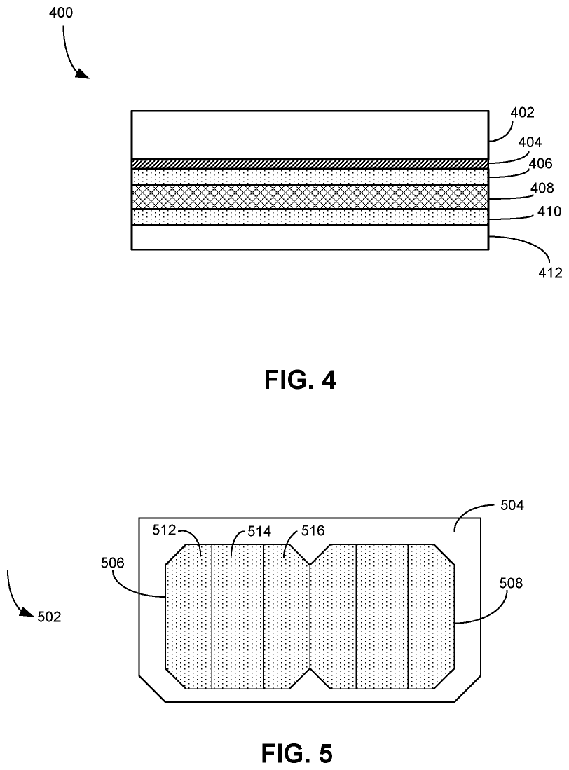

FIG. 4 shows a cross-section of an exemplary photovoltaic roof tile, according to an embodiment. Solar cell or array of solar cells 408 can be encapsulated between top glass cover 402 and back cover 412, which can be fortified glass or a regular PV backsheet. In alternative embodiments, back cover 412 can also be made of other materials, such as flexible glass, garolite, glass-epoxy laminate (e.g., FR-4), etc. Top encapsulant layer 406, which can be based on a polymer, can be used to seal top glass cover 402 and solar cell or array of solar cells 408. Specifically, encapsulant layer 406 may include polyvinyl butyral (PVB), thermoplastic polyolefin (TPO), ethylene vinyl acetate (EVA), or N,N′-diphenyl-N,N′-bis(4-methylphenyl)-1,1′-diphenyl-4,4′-diamine (TPD). Similarly, lower encapsulant layer 410, which can be based on a similar material, can be used to seal array of solar cells 408 and back cover 412. A PV roof tile can also contain other optional layers, such as an optical filter or coating layer or a layer of nanoparticles for providing desired color appearances. In the example of FIG. 4, module or roof tile 400 also contains an optical filter layer 404.

FIG. 5 illustrates a top view of an exemplary solar roof tile that encapsulates a cascaded string, according to one embodiment. Solar roof tile 502 includes top glass cover 504 and solar cells 506 and 508. The bottom cover (e.g., backsheet) of solar roof tile 502 is out of view in FIG. 5. Solar cells 506 and 508 can be conventional square or pseudo-square solar cells, such as six-inch solar cells. In some embodiments, solar cells 506 and 508 can each be divided into three separate pieces of similar size. For example, solar cell 506 can include strips 512, 514, and 516. These strips can be arranged in such a way that adjacent strips are partially overlapped at the edges, similar to the ones shown in FIGS. 2A-2B. For simplicity of illustration, the electrode grids, including the finger lines and edge busbars, of the strips are not shown in FIG. 5. In addition to the example shown in FIG. 5, a solar roof tile can contain fewer or more cascaded strips, which can be of various shapes and sizes.

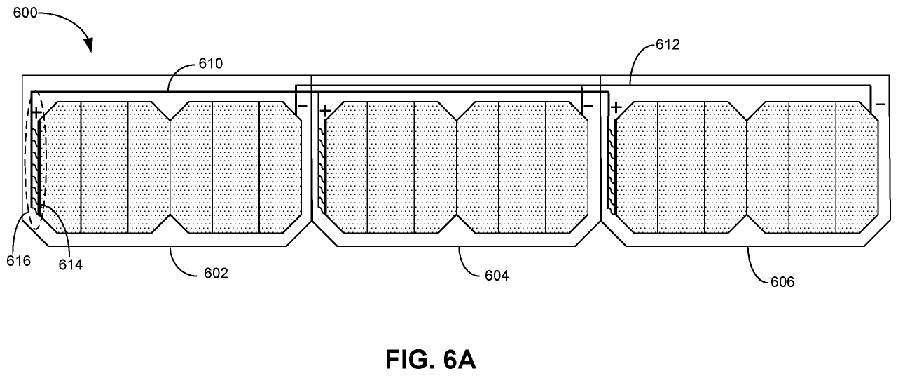

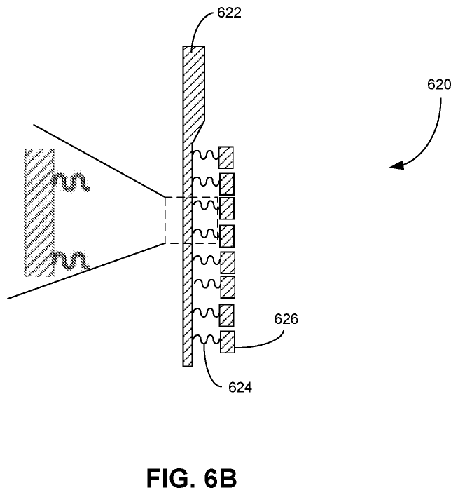

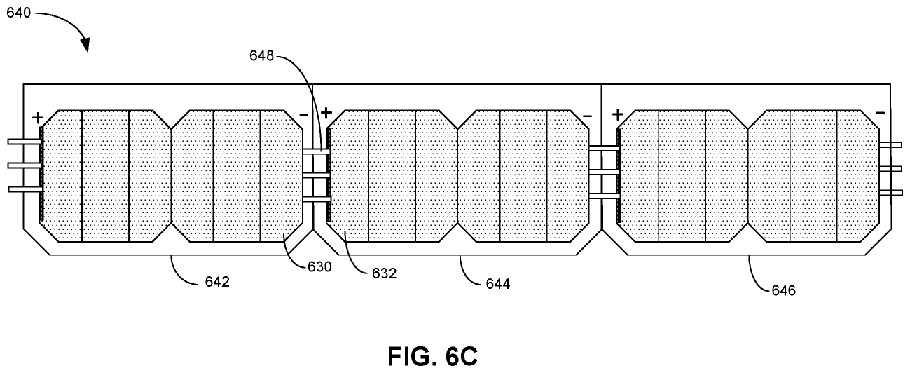

To facilitate more scalable production and easier installation, multiple photovoltaic roof tiles can be fabricated together, while the tiles are linked in a rigid or semi-rigid way. FIG. 6A shows the top view of an exemplary multi-tile module, according to one embodiment. Multi-tile module 600 can include PV roof tiles 602, 604, and 606 arranged side by side. Each PV roof tile can include six cascaded strips encapsulated between the front and back covers, meaning that busbars located at opposite edges of the cascaded string of strips have opposite polarities. For example, if the leftmost edge busbar of the strips in PV roof tile 602 has a positive polarity, then the rightmost edge busbar of the strips will have a negative polarity. Serial connections can be established among the tiles by electrically coupling busbars having opposite polarities, whereas parallel connections can be established among the tiles by electrically coupling busbars having the same polarity.

In the example shown in FIG. 6A, the PV roof tiles are arranged in such a way that their sun-facing sides have the same electrical polarity. As a result, the edge busbars of the same polarity will be on the same left or right edge. For example, the leftmost edge busbar of all PV roof tiles can have a positive polarity and the rightmost edge busbar of all PV roof tiles can have a negative polarity, or vice versa. In FIG. 6A, the left edge busbars of all strips have a positive polarity (indicated by the “+” signs) and are located on the sun-facing (or front) surface of the strips, whereas the right edge busbars of all strips have a negative polarity (indicated by the “−” signs) and are located on the back surface. Depending on the design of the layer structure of the solar cell, the polarity and location of the edge busbars can be different from those shown in FIG. 6A.

A parallel connection among the tiles can be formed by electrically coupling all leftmost busbars together via metal tab 610 and all rightmost busbars together via metal tab 612. Metal tabs 610 and 612 are also known as connection buses and typically can be used for interconnecting individual solar cells or strings. A metal tab can be stamped, cut, or otherwise formed from conductive material, such as copper. Copper is a highly conductive and relatively low-cost connector material. However, other conductive materials such as silver, gold, or aluminum can be used. In particular, tin, silver, or gold can be used as a coating material to prevent oxidation of copper or aluminum. In some embodiments, alloys that have been heat-treated to have super-elastic properties can be used for all or part of the metal tab. Suitable alloys may include, for example, copper-zinc-aluminum (CuZnAl), copper-aluminum-nickel (CuAlNi), or copper-aluminum-beryllium (CuAlBe). In addition, the material of the metal tabs disclosed herein can be manipulated in whole or in part to alter mechanical properties. For example, all or part of metal tabs 610 and 612 can be forged (e.g., to increase strength), annealed (e.g., to increase ductility), and/or tempered (e.g. to increase surface hardness).

The coupling between a metal tab and a busbar can be facilitated by a specially designed strain-relief connector. In FIG. 6A, strain-relief connector 616 can be used to couple busbar 614 and metal tab 610. Such strain-relief connectors are needed due to the mismatch of the thermal expansion coefficients between metal (e.g., Cu) and silicon. As shown in FIG. 6A, the metal tabs (e.g., tabs 610 and 612) may cross paths with strain-relief connectors of opposite polarities. To prevent an electrical short of the photovoltaic strips, portions of the metal tabs and/or strain-relief connectors can be coated with an insulation film or wrapped with a sheet of insulation material.

FIG. 6B shows a detailed view of an exemplary strain-relief connector, according to one embodiment. In FIG. 6B, strain-relief connector 620 can include elongated connection member 622, a number of curved metal wires (e.g., curved metal wire 624), and a number of connection pads (e.g., connection pad 626). The connection pads can be used to couple strain-relief connector 620 to a corresponding edge busbar. Elongated connection member 622 can extend along a direction substantially parallel to the to-be-coupled busbar of a photovoltaic structure. The curved metal wires can extend laterally from elongated connection member 622 in a non-linear manner (i.e., having non-linear geometry), as shown by the amplified view. Non-linear geometry can include paths that centrally follow a curved wire (e.g., a path that extends along a series of centermost points located between outermost edges) or along any face or edge of the wire. A curved wire having non-linear geometry can have, but does not require, symmetry along the path of elongation. For example, one edge, or portion of an edge, of a curved wire can be straight and an opposite edge can include one or more curves, cuts, or extensions. Curved wires having non-linear geometry can include straight portions before, after, and/or between non-linear portions. Non-linear geometry can include propagating paths that extend laterally along a first axis (e.g., X axis) while alternating direction in negative and positive directions of one or more other axes (e.g., Y axis and/or Z axis) that are perpendicular to the first axis, in a repetitive manner, such as a sine wave or helix. While the curved wires disclosed herein use curved profiles, non-linear geometry can be constructed from a series of straight lines; for example, propagating shapes, such as square or sawtooth waves, can form non-linear geometry. These curved wires can relieve the strain generated due to the mismatch of thermal expansion coefficients between the metal connector and the Si-based photovoltaic structure.

In some embodiments, each curved metal wire can be attached to a connection pad. For example, curved metal wire 624 can be attached to connection pad 626. In alternative embodiments, more than one (e.g., two or three) curved wires can be attached to a connection pad. The elongated connection member 622, the curved wires, and the connection pads can be formed (e.g., stamped or cut) from a single piece of material, or they can be attached to each other by any suitable electrical connection, such as by soldering, welding, or bonding. A more detailed description of such strain-relief connectors and the coupling between the strain-relief connectors and the edge busbars can be found in U.S. patent application Ser. No. 15/900,600, Attorney Docket No. P0390-1NUS, filed Feb. 20, 2018, and entitled “METHOD FOR ATTACHING CONNECTOR TO SOLAR CELL ELECTRODES IN A SOLAR ROOF TILE,” the disclosure of which is incorporated herein by reference in its entirety.

In some embodiments, instead of parallelly coupling the tiles within a tile module using stamped metal tabs and strain-relief connectors as shown in FIG. 6A, one can also form serial coupling among the tiles. FIG. 6C shows the top view of an exemplary multi-tile module, according to one embodiment. Tile module 640 can include solar roof tiles 642, 644, and 646. Each tile can include a number (e.g., six) of cascaded solar cell strips arranged in a manner shown in FIGS. 2A and 2B. Furthermore, metal tabs can be used to interconnect photovoltaic strips enclosed in adjacent tiles. For example, metal tab 648 can connect the front side of strip 632 with the back side of strip 630, creating a serial coupling between strips 630 and 632. Although the example in FIG. 6C shows three metal tabs interconnecting the photovoltaic strips, other numbers of metal tabs can also be used. Furthermore, each solar roof tile can contain fewer or more cascaded strips, which can be of various shapes and sizes.

For simplicity of illustration, FIGS. 6A and 6C do not show the inter-tile spacers that provide support and facilitate mechanical and electrical coupling between adjacent tiles. Detailed descriptions of such inter-tile spacers can be found in U.S. patent application Ser. No. 15/900,636, Attorney Docket No. P0363-1NUS, filed Feb. 20, 2018, and entitled “INTER-TILE SUPPORT FOR SOLAR ROOF TILES,” the disclosure of which is incorporated herein by reference in its entirety.

### Coupling Between Adjacent Strips in a Solar Roof Tile

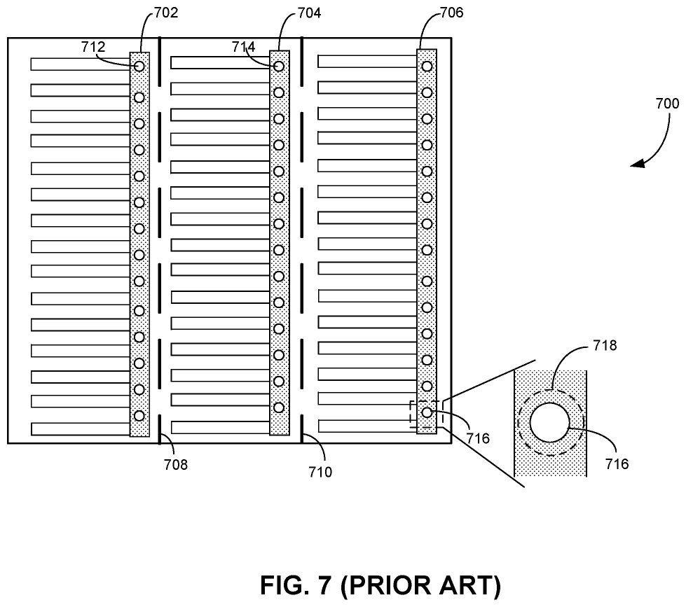

To ensure electrical and mechanical coupling between adjacent edge-overlapped strips, conductive paste has been applied on the edge busbars. In most cases, the conductive paste can be applied onto the busbars before a square solar cell is divided into multiple smaller pieces. FIG. 7 illustrates a photovoltaic structure with conductive paste applied onto its busbars (prior art). In the example shown in FIG. 7, photovoltaic structure 700 can include three busbars 702, 704, and 706. On each of the busbars, conductive paste, shown in the example in FIG. 7 as individual droplets, can be deposited. For example, paste droplet 712 is deposited on busbar 702, and paste droplet 714 is deposited on busbar 704. Dashed lines 708 and 710 mark the locations of the laser scribes. As one can see, precise application of the conductive paste can require sophisticated and expensive tools. Moreover, the fluid nature of the conductive paste means that the paste may overflow, either during or after paste application, and may come into contact with the edge of the strip, which can lead to shunting. Similarly, when the edge busbars are stacked against each other and the conductive paste cured, the paste droplets, such as droplet 716, can expand. FIG. 7 also shows an amplified view of paste droplet 716, with dashed circle 718 representing the cured version of paste droplet 716. After curing, the diameter of the paste droplets may expand to twice as large as the original paste droplets. There is also a chance for the expanded paste droplets to overflow beyond the edge of the strip.

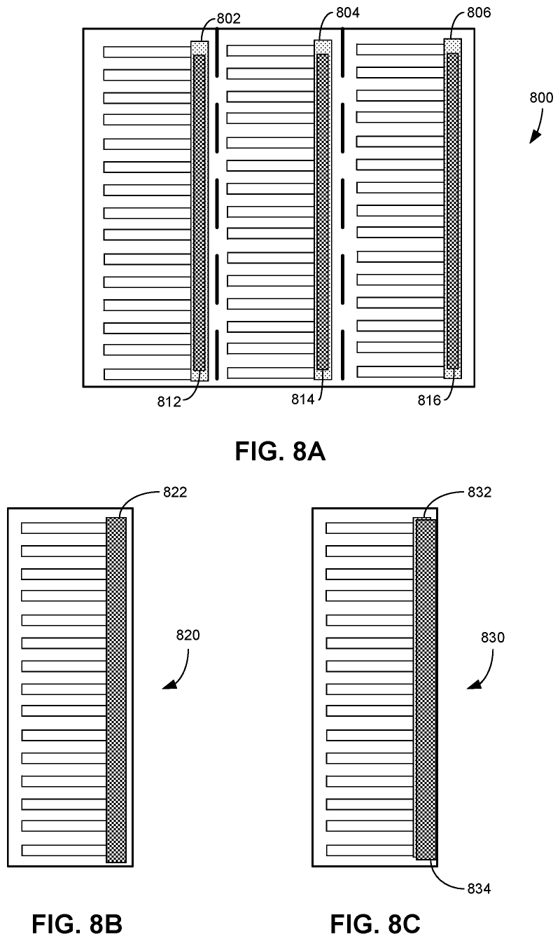

To enable a simpler and more reliable bonding mechanism, in some embodiments, instead of conductive paste, a layer of adhesive conductive film can be applied onto the edge busbars. In some embodiments, the adhesive conductive film can be applied before a larger solar cell is divided into smaller pieces. FIG. 8A illustrates a surface of a photovoltaic structure with adhesive conductive films applied onto its busbars, according to one embodiment. In FIG. 8A, undivided photovoltaic structure 800 includes three busbars 802, 804, and 806. Each busbar can be covered by a layer of adhesive conductive film. For example, busbars 802, 804, and 806 are covered, respectively, by adhesive conductive film layers 812, 814, and 816. Exemplary adhesive conductive films can include anisotropic conductive films (ACFs), which can be epoxy or acrylic based. For example, an exemplary ACF can include conductive particles (e.g., Ni or Au particles, or Ni or Au coated polymer particles) embedded in or deposited onto an adhesive (e.g., epoxy or acrylic) layer. Moreover, double-sided conductive tapes can also be used to bond the overlapping busbars. Because the size and shape of the adhesive conductive films or tapes can be well defined, the possibility of shunting after bonding can be significantly reduced compared to the cases where conductive paste was used. Moreover, the precise application of the adhesive conductive film at the edges of neighboring photovoltaic strips can reduce the overlapping area while providing a significant processing buffer. The reduced overlapping area between adjacent strips can increase the amount of light absorbed by the photovoltaic strips, thus increasing the total power output of the photovoltaic roof tile.

For simplicity of illustration, in FIG. 8A, the adhesive conductive films are shown as partially covering the busbars. Although using a film layer that is slightly smaller than the busbar surface can increase tolerance to film application error, in practice, it is also possible for an adhesive conductive film to cover the entire surface of a busbar. Moreover, it is also possible to apply the film after the larger solar cell has been divided into multiple smaller pieces. FIG. 8B illustrates a surface of a photovoltaic strip with an adhesive conductive film applied onto its edge busbar, according to one embodiment. In FIG. 8B, photovoltaic strip 820 can be obtained by dividing a larger photovoltaic structure (e.g., square solar cell 800 shown in FIG. 8A) into multiple (e.g., three) smaller pieces, and can include an edge busbar on each of its two surfaces. Only one surface of the strip is shown in FIG. 8B. Adhesive conductive film 822 covers the entire surface of an edge busbar (out of view in FIG. 8B). This configuration can ensure sufficient bonding between the overlapped edge busbars. In some embodiments, the adhesive conductive film can be pressure-cured, such as in the case of a double-sided adhesive conductive tape. In some embodiments, the adhesive conductive film can be heat-cured, such as in the case of an ACF layer. To prevent damages to the photovoltaic structures, in some embodiments, the ACF layer is selected in such a way that the curing temperature is below 200° C. (e.g., 150° C.) and the curing time is less than 20 seconds (e.g., between 5 and 15 seconds). In some embodiments, the curing of the ACF layer can occur during the lamination of the roof tile.

As discussed previously, a fabrication system that uses adhesive conductive films as bonding media can be much more tolerant of misalignment during application of the films. FIG. 8C illustrates a surface of a photovoltaic strip with an adhesive conductive layer applied onto its edge busbar, according to one embodiment. In FIG. 8C, photovoltaic strip 830 can include an edge busbar 832, and an adhesive conductive film layer 834 partially covers edge busbar 832. Note that this partial coverage is due to fabrication error. More specifically, when the film-application tool applies the adhesive conductive film 834, it slightly misaligns the film with the surface of edge busbar 832. However, such a slight misalignment usually does not create negative effects (e.g., additional shading or shunting) to the performance of the photovoltaic structure.

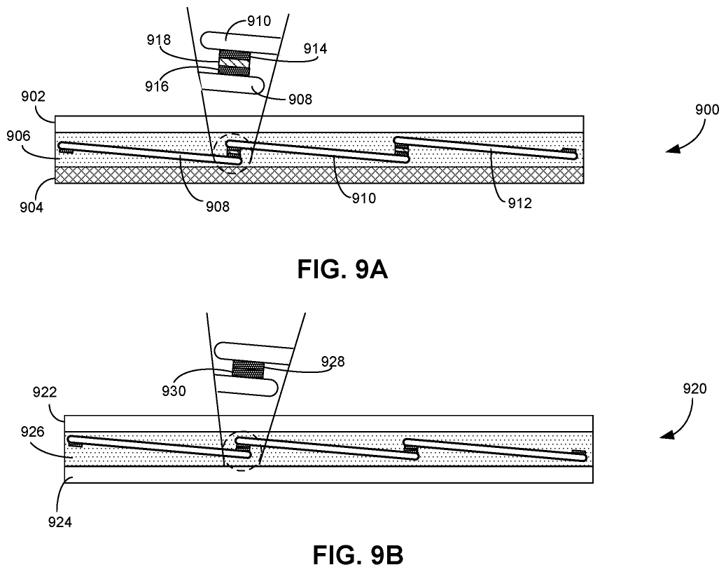

FIG. 9A illustrates the cross-section of an exemplary photovoltaic roof tile, according to an embodiment. PV roof tile 900 can include front cover 902, back cover 904, encapsulant 906, and a cascaded string that includes multiple photovoltaic strips (i.e., strips 908, 910, and 912) arranged in such a way that edge busbars of adjacent strips overlap and are coupled to each other electrically and mechanically via an adhesive conductive film. For example, as shown by the amplified view, the edge busbar of strip 910 (i.e., busbar 914) overlaps with the edge busbar of strip 908 (i.e., busbar 916). An adhesive conductive film layer 918 is positioned between busbars 914 and 916, mechanically and electrically coupling busbars 914 and 916.

Front cover 902 can be made of tempered glass, and back cover 904 can be made of tempered glass or non-transparent materials. For example, back cover 904 can include a photovoltaic backsheet, which can be based on polyethylene terephthalate (PET) or polyvinyl fluoride (PVF). Edge busbars 914 and 916 can include electroplated Cu. In some embodiments, a protective layer can cover the sidewalls of the electroplated Cu busbars. The protective layer can include corrosion-resistant metal, such as Sn or Ag. Alternatively, the protective layer can include an organic solderability preservative (OSP) coating, which can include imidazole or its derivatives.

Adhesive conductive film layer 918 can include an ACF layer of a double-sided electrical conductive tape. Adhesive conductive film layer 918 can first be applied onto one of the overlapping edge busbars. For example, adhesive conductive film layer 918 can first be applied onto the top surface of edge busbar 916 of photovoltaic strip 908. When strips 908 and 910 are arranged to have their adjacent edges overlapping each other, edge busbar 914 can be stacked against edge busbar 916, with adhesive conductive film layer 918 sandwiched between edge busbars 914 and 916. After curing, adhesive conductive film layer 918 can mechanically and electrically bond edge busbars 914 and 916. Such a curing process can occur the same time encapsulant 906 is cured.

In some embodiments, if both the front and back covers are made of glass, the rigidity of the covers can make it possible for the stacked edge busbars to be held together by pressure, without any adhesive. In such a scenario, the adhesive conductive film layer becomes optional. FIG. 9B illustrates the cross-section of an exemplary photovoltaic roof tile, according to an embodiment. In the example shown in FIG. 9B, PV roof tile 920 can include front glass cover 922, back glass cover 924, encapsulant 926, and a cascaded string that includes multiple photovoltaic strips. Similar to the example shown in FIG. 9A, the multiple photovoltaic strips between front glass cover 922 and back glass cover 924 have been arranged in such a way that their adjacent edge busbars are stacked against each other. More specifically, as shown by the amplified view, the edge busbars of the adjacent photovoltaic strips (e.g., edge busbars 928 and 930) are stacked against each other directly, without an adhesive in between. A metal-to-metal contact between surfaces of edge busbars 928 and 930 can ensure electrical coupling between the two edge busbars.

### Fabrication of a Photovoltaic Module

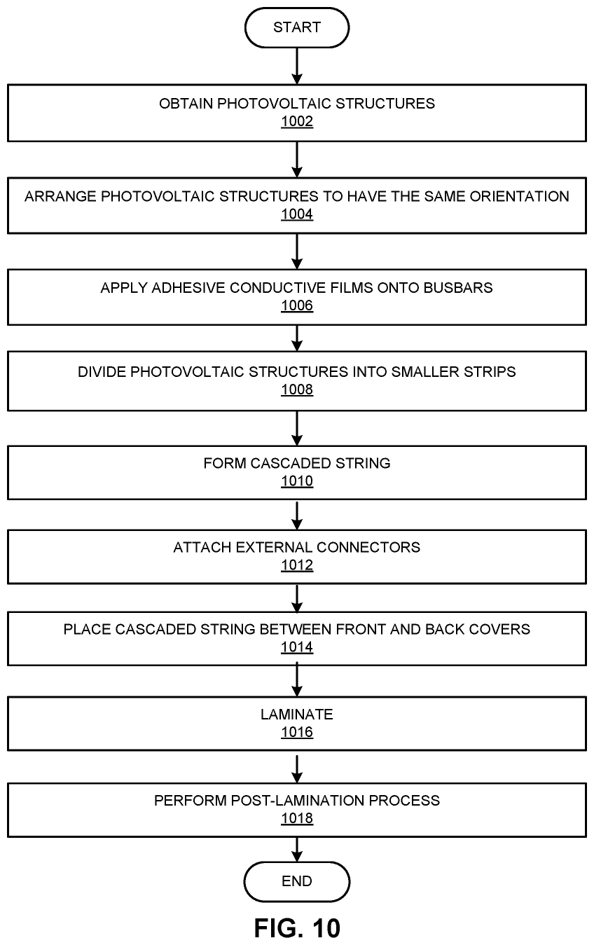

FIG. 10 presents a flowchart illustrating an exemplary process for fabricating a photovoltaic module, according to an embodiment. The photovoltaic module can be a PV roof tile. During fabrication, a number of photovoltaic structures can be obtained (operation 1002). The photovoltaic structures can include conventional square or pseudo-square solar cells. Cu-based metal grids have been deposited on both surfaces of the photovoltaic structures. In some embodiments, exposing surfaces of the Cu metal grid lines (e.g., busbars and finger lines) can be covered by a corrosion-protective layer, such as a corrosion-resistant metal layer or an OSP coating.

The photovoltaic structures can be arranged in such a way that their surfaces with the same polarity are facing the same direction (operation 1004). For example, the photovoltaic structures can be arranged to have their positive-polarity surfaces facing upwards. A layer of adhesive conductive film can then be deposited onto the busbars on the upwardly facing surfaces of the photovoltaic structures (operation 1006). In some embodiments, an automatic film-application tool, such as a film or tape dispenser with a robotic arm can be used to apply the adhesive conductive film onto the busbars.

Subsequently, the square or pseudo-square solar cells can be divided into smaller strips by laser scribing and cleaving (operation 1008) and a cascaded string can be formed by arranging the strips in such a way that they overlap at the edges with corresponding edge busbars stacked against each other and the adhesive conductive film sandwiched between the stacked busbars (operation 1010). Detailed descriptions about the formation of a cascaded string of photovoltaic strips can be found in U.S. patent application Ser. No. 14/826,129, Attorney Docket No. P103-3NUS, entitled “PHOTOVOLTAIC STRUCTURE CLEAVING SYSTEM,” filed Aug. 13, 2015; U.S. patent application Ser. No. 14/866,776, Attorney Docket No. P103-4NUS, entitled “SYSTEMS AND METHODS FOR CASCADING PHOTOVOLTAIC STRUCTURES,” filed Sep. 25, 2015; and U.S. patent application Ser. No. 14/804,306, Attorney Docket No. P103-5NUS, entitled “SYSTEMS AND METHODS FOR SCRIBING PHOTOVOLTAIC STRUCTURES,” filed Jul. 20, 2015; the disclosures of which are incorporated herein by reference in their entirety.

To enable inter-string electrical coupling, external conductive connectors can be attached to exposed busbars of the cascaded string (operation 1012). The external conductive connectors can include strain-relief connectors, which can be made of stamped metal. In some embodiments, attaching an external conductive connector to an edge busbar can involve applying electrically conductive adhesive (ECA) paste, which is isotropic in nature, onto the surface of the external connector or the edge busbar. The ECA paste, after being cured, can create a strong mechanical and electrical bond between the external connector and the edge busbar. If the external conductive connector includes a strain-relief connector, the ECA paste can be applied onto the connection pads of the strain-relief connector.

The cascaded string of PV structures along with the attached external connectors can then be placed between a front cover and a back cover, embedded in encapsulant (operation 1014). A lamination operation can be performed to encapsulate the string of PV structures along with the attached external connectors inside the front and back covers (operation 1016). During the lamination process, the adhesive conductive films sandwiched between the stacked edge busbars can also be cured, securely bonding the stacked edge busbars. Similarly, the ECA paste between the external connectors and the edge busbars can also be cured, securely bonding the external connectors to the edge busbars. A post-lamination process (e.g., trimming of overflowed encapsulant and attachment of other roofing components) can then be performed to complete the fabrication of a PV roof tile (operation 1018).

In some embodiments, when the front and back covers are both glass covers, it is also possible to skip the film-application operation. As discussed previously, even without the adhesive conductive film, the stacked edge busbars can be held in position by the encapsulant and rigid covers.

The foregoing descriptions of various embodiments have been presented only for purposes of illustration and description. They are not intended to be exhaustive or to limit the present system to the forms disclosed. Accordingly, many modifications and variations will be apparent to practitioners skilled in the art. Additionally, the above disclosure is not intended to limit the present system.

What is claimed is:

1. A photovoltaic roof tile, comprising:
a front cover;
a back cover; and
a plurality of photovoltaic structures positioned between the front and back covers;
wherein a respective photovoltaic structure comprises a first edge busbar positioned near an edge of a first surface and a second edge busbar positioned near an opposite edge of a second surface;
wherein the plurality of photovoltaic structures is arranged in such a way that the first edge busbar of a first photovoltaic structure overlaps the second edge busbar of an adjacent photovoltaic structure with a layer of adhesive conductive film sandwiched between the first and second edge busbars, thereby resulting in the plurality of photovoltaic structures forming a serially coupled string.

2. The photovoltaic roof tile of claim 1, wherein the front cover comprises tempered glass.

3. The photovoltaic roof tile of claim 1, wherein the back cover comprises tempered glass, a photovoltaic backsheet, flexible glass, garolite, or glass-epoxy laminate.

4. The photovoltaic roof tile of claim 1, wherein the adhesive conductive film layer comprises an anisotropic conductive film (ACF) or a double-sided conductive tape.

5. The photovoltaic roof tile of claim 1, wherein the adhesive conductive film is deposited onto a surface of at least one of the first and second edge busbars.

6. The photovoltaic roof tile of claim 5, wherein the adhesive conductive film layer is configured to completely cover the surface of the at least one of the first and second edge busbars.

7. The photovoltaic roof tile of claim 5, wherein the adhesive conductive film layer is configured to partially cover the surface of the at least one of the first and second edge busbars.

8. The photovoltaic roof tile of claim 1, further comprising one or more external conductive connectors coupled to one or more exposed edge busbars of the serially coupled string.

9. The photovoltaic roof tile of claim 8, wherein the external conductive connectors comprise a strain-relief connector, and wherein the strain-relief connector comprises:
an elongated connection member;
a number of curved metal wires, laterally extended from one side of the elongated connection member; and
a number of connection pads.

10. The photovoltaic module of claim 1, wherein the first and second edge busbars comprise a Cu layer and a corrosion-protective layer, and wherein the corrosion-protective layer comprises a corrosion-resistant metal layer or an organic solderability preservative (OSP) coating.

11. A method for fabricating a photovoltaic roof tile, the method comprising:
obtaining a number of photovoltaic structures, wherein a respective photovoltaic structure comprises a first edge busbar positioned near an edge of a first surface and a second edge busbar positioned near an opposite edge of a second surface;
applying an adhesive conductive film layer on at least one of the first and second edge busbars;
forming a cascaded string of photovoltaic structures by arranging the photovoltaic structures in such a way that the first edge busbar of a first photovoltaic structure overlaps the second edge busbar of an adjacent photovoltaic structure with the adhesive conductive film layer sandwiched between the first and second edge busbars; and
laminating the cascaded string of photovoltaic structures between a front cover and a back cover.

12. The method of claim 11, wherein the front cover comprises tempered glass.

13. The method of claim 11, wherein the back cover comprises tempered glass or a photovoltaic backsheet.

14. The method of claim 11, wherein the adhesive conductive film layer comprises an anisotropic conductive film (ACF) or a double-sided conductive tape.

15. The method of claim 11, wherein the adhesive conductive film layer is configured to completely cover the surface of the at least one of the first and second edge busbars.

16. The method of claim 11, wherein the adhesive conductive film layer is configured to partially cover the surface of the at least one of the first and second edge busbars.

17. The method of claim 11, further comprising attaching an external conductive connector to an exposed edge busbar of the cascaded string.

18. The method of claim 17, wherein the external conductive connector comprises a strain-relief connector, and wherein the strain-relief connector comprises:
an elongated connection member;
a number of curved metal wires, laterally extended from one side of the elongated connection member; and
a number of connection pads.

19. The method of claim 18, wherein attaching the external conductive connector comprises applying electrically conductive adhesive (ECA) paste between the connection pads and the exposed edge busbar, forming an electrical and mechanical bond.

20. The method of claim 11, wherein the first and second edge busbars comprise a Cu layer and a corrosion-protective layer, and wherein the corrosion-protective layer comprises a corrosion-resistant metal layer or an organic solderability preservative (OSP) coating.
